(19) United States
(12) Patent Application Publication
(10) Pub. No.: US 2014/0361787 A1
(43) Pub. Date: Dec. 11, 2014

(54) Apparatus for Measuring High Frequency Electromagnetic Noise in Printed Circuit Boards and Measurement Method Therefor

(71) Applicant: Hitachi, Ltd., Chiyoda-ku, Tokyo (JP)

(72) Inventor: Umberto Paoletti, Tokyo (JP)

(21) Appl. No.: 14/371,637

(22) PCT Filed: Nov. 20, 2012
(86) PCT No.: PCT/JP2012/007446

§ 371 Date: Jul. 10, 2014

(30) Foreign Application Priority Data
Feb. 9, 2012 (JP) 2012-025718

(51) Int. Cl. G01R 31/02; G01R 23/20

(52) U.S. Cl. CPC G01R 31/02; G01R 23/20
USPC 324/537

(57) ABSTRACT

An apparatus and a method for measuring high frequency electromagnetic noise on the power supply planes of printed circuit boards (PCBs). The apparatus comprises a printed reverberation board (PRB) with curved edges that generates a strong sensitivity of the results to the boundary conditions. The PCB under test is inserted into a hole in the PRB and the power supply planes are connected to the PRB's first and second layer, in order to convey the noise into the device. Tuners are provided in to order obtain a statistically significant number of measurements with different boundary conditions. Measurement are conducted on the device ports. (See FIG. 1)

### FIELD OF THE INVENTION

The present invention relates to the measurement of electromagnetic noise generated by active printed circuit board (PCB) components, and in particular to the power supply noise generated by simultaneous switching of large scale integration (LSI) circuits.

### BACKGROUND OF THE INVENTION

Power supply noise of PCBs is a source of high frequency electromagnetic interferences (EMI), and it is mainly generated by simultaneous switching of LSIs. The simultaneous switching noise (SSN) propagates as an electromagnetic (EM) wave between the power supply planes and most of it is reflected back by the board edges (e.g. FIG. 2), creating resonances that are dependent on the board layout.

Typically, bypass capacitors are used to reduce power supply noise, as shown schematically in FIG. 2. The capacitors in FIG. 2 are usually placed on the top of the PCB and are not embedded in the board, although sometimes they are. A simplified equivalent circuit of one powergrand plane port at one LSI pin (or trace) is shown in FIG. 3. The effectiveness of bypass capacitor C_{b} in reducing the noise is dependent on the noise source I_{g}, on the source impedance Z_{g}, but also on the power supply plane input impedance Zᵢₙ, which depends on the board layout.

In order to quantitatively design a configuration of bypass capacitors suitable for EMI, noise source, noise source impedance and power supply input impedance must be estimated. Since an estimation based on simulations is very difficult and often not practicable, the required quantities must be estimated from measurements.

Measurements are usually done at one trace (or pin) location (A in FIG. 4), before entering into the power supply planes. In particular, measurements with only one known value of the power supply impedance allows in principle to obtain only a noise model with an ideal current source, as shown in FIG. 5. In order to obtain a model including both noise source and noise source impedance, as shown in FIG. 6, measurements with at least two known different values of the power supply impedance must be conducted.

There are several problems related with this type of power supply noise measurements. A method for changing the power supply impedance is necessary. The power supply input impedance must be known, but it is difficult to obtain, particularly at frequencies above 1 GHz. Measurements on pins and traces at high frequencies (typically above 1 GHz) are difficult. Some of the LSI pins are not always accessible, for example when there are vias just below a ball grid array (BGA) package.

An alternative approach is that of measuring the power supply noise in a different location after entering into the power supply planes (B in FIG. 4). There are special problems related to this type of measurements. Since the noise already entered into the power ground planes, it is impossible to distinguish the contributes of single pins. A suitable location of the measurement port is not clear due the board resonances.

Eventually, measurements in many ports in different board positions must be conducted. A procedure to determine source and impedance source is not available.

### DESCRIPTION OF THE RELATED ART

A standard measurement equipment to measure electromagnetic noise emitted by measurement equipment is the reverberation chamber. This equipment has been known for a long time. Some recent patents extending the original reverberation chamber are for example the patent documents U.S. 2003/0184417 and U.S. 2011/0043222. The measurement method is described in the non-patent document 1, that is the International Standard IEC 61000-4-21.

The non-patent document 2 describes a quarter-bow-tie shaped, flat and air-filled conducting box with tuners and coaxial ports to study the statistics of the impedance matrix between the ports.

### CITATION LIST

### Patent Literature

[PTL 1]

U.S. 2003/0184417A1

[PTL 2]

U.S. 2011/0043222A1

### Non Patent Literature

[NPL 1]

International Standard IEC 61000-4-21: “Electromagnetic Compatibility (EMC)—Part 4-21: Testing and measurement techniques—Reverberation chamber test methods”, Ed. 2.0, 2011.

[NPL 2]

S. D. Hemmady: “A Wave-Chaotic Approach to Predicting and Measuring Electromagnetic Quantities in Complicated Enclosures,” Ph.D. thesis, University of Maryland, 2006.

[NPL 3]

V. Galdi, I. M. Pinto, L. B. Felsen: “Wave propagation in ray-chaotic enclosures: paradigms, oddities and examples,” IEEE Antennas and Propagation magazine, vol. 47, no. 1, pp. 62-81. February 2005.

### SUMMARY OF INVENTION

### Technical Problem

The main subject of the present invention is to measure high frequency power supply noise in a way suitable to extract an LSI noise source model. In order to do this, some ways to solve the several problems mentioned in the background must be provided, namely: a practical way to change the power supply input impedance, a method to have information about the input impedance, high frequency measurement ports in the board, a way to consider the effect of all the pins, a way to determine a suitable measurement position, a way to make measurements at one or few ports, at least one possible procedure to extract a noise model.

### Solution to Problem

The present invention is associated with a new approach to the problem of extracting the LSI noise source model, which does not require knowledge of the power supply impedance at each measurement, but only the statistical distribution of the power supply impedance over a relatively large number of measurements. A schematic example of a statistical distribution of the power supply impedance is shown in FIG. 7.

A new definition of noise model is also disclosed in the present invention. The port in the prior art is defined in terms of voltage and current at each LSI pin or trace, and one port for each pin of interest is used. In the present invention an equivalent port is introduced, that represents the current and the power delivered by the LSI as a whole to the power supply planes. The equivalent port refers to an extended region of space below the LSI that encloses many vias at the same time, as shown schematically with the shadowed region in FIG. 8. The source model is shown in FIG. 9, where the equivalent current source I_{g} represents the current injected or induced by all the power supply plane pins, and the source impedance Z_{g} represents the dependency of I_{g} on the load impedance.

An important feature of the present invention is the statistical uniformity of the power supply planes of the invented printed circuit board except for some special regions, which strictly speaking means that the statistical distribution of the outcomes of a set of experiments is the same in any position of the board. For example, the statistical distribution of the power supply input impedance in one set of measurements in one board position is the same as the statistical distribution in a second position, when both are at a distance larger than half-wavelength from the board edges. In some realizations of the present invention the statistical uniformity must be intended in a less strict sense, that is the statistical distribution of the outcomes of a set of experiments can be described as the combination of a strictly statistically uniform component and a component that is dependent on the position.

In order to realize the statistical uniformity, a large number of cavity modes must be present around one particular frequency, in such a way that by changing many times some boundary conditions, the electromagnetic field distribution can be changed as well.

The statistical uniformity is efficiently obtained when wave chaotic conditions are realized inside the power supply planes. The meaning of wave chaotic conditions is that a small change of the boundary conditions generate a very different electromagnetic field distribution.

### Composition

The present invention aims to provide a PCB suitable to generate a known statistical uniform environment, which allows to create a known statistical distribution of the power supply impedance, and to make measurements in almost any position. In the following this PCB will be called printed reverberation board (PRB). The present invention provides also one or a plurality of tuners, in order to automatically change the boundary conditions, and one or a plurality of high frequency measurement ports. The invention comprises a hole in the PRB in order to insert the equipment under test (EUT).

The PRB can be realized with a shape suitable to generate wave chaotic conditions, that is a shape such that an ideal wave ray generates non repetitive paths when it is reflected at the board edges. The PRB must have low dielectric and conducting loss and large dimensions with respect of the wavelength at the frequencies of interest (six wavelength are considered to be sufficient according to the present scientific literature). The low-loss requirement is necessary in order to have a high quality factor, which corresponds to a large variation of the power supply impedance.

The present invention also comprises a method of measuring the power supply noise. The EUT is connected to the PRB all along the EUT perimeter, the noise power is injected to the PRB, the noise is measured at the measurement ports, the tuners are rotated and the measurements are repeated.

The present invention also provides a measurements system, comprising the PRB, the tuners, the ports, the motors to rotate the tuners, the measurement equipment, the cable to connect the ports to the measurement equipments, and eventually other components like DC blocks, attenuators, amplifiers or filters to conduct the measurements.

In other embodiments of the present inventions, the ports are not present and measurements are conducted at the LSI pins or traces. The hole for the EUT is not present in other embodiments, and the LSI is mounted directly on the PRB. In other embodiments the tuners are external to the PRB and they change the boundary conditions by means of electromagnets. In other embodiments variable capacitors are used to change the power supply impedances, together with the tuners or instead of the tuners.

### Advantageous Effects of Invention

With the proposed invention the power supply input impedance can be changed automatically. The invention is particularly suitable to measurements at high frequency, for example above 1 GHz. Due to the statistical uniformity, measurements in one or few ports are sufficient, and almost any measurement position is possible. Models for the statistical distribution of the impedance matrix between two positions in the parallel planes are available in the scientific literature. Due to the special meaning given to the source model, all the LSI pins of interest can be considered, and distinguishing among the pins becomes unnecessary.

### BRIEF DESCRIPTION OF DRAWINGS

[FIG. 1]

FIG. 1: Simplified diagram of the invention.

[FIG. 2]

FIG. 2: Simplified diagram of the power supply noise emission mechanism.

[FIG. 3]

FIG. 3: Simplified equivalent circuit of power supply port at the location of a bypass capacitor on a trace before entering the power ground planes.

[FIG. 4]

FIG. 4: Simplified diagram of measurement positions of PCB noise.

[FIG. 5]

FIG. 5: Ideal source model and power supply impedance.

[FIG. 6]

FIG. 6: Source model with source impedance and power supply impedance.

[FIG. 7]

FIG. 7: Simplified diagram of statistical distribution of magnitude of input impedance at frequency f.

[FIG. 8]

FIG. 8: Simplified diagram of the equivalent LSI noise port.

[FIG. 9]

FIG. 9: Noise source equivalent port.

[FIG. 10]

FIG. 10: Simplified diagram of the invention with EUT.

[FIG. 11]

FIG. 11: Simplified diagram of connection method of EUT to PRB by means of blind vias.

[FIG. 12]

FIG. 12: Simplified diagram of connection method of EUT to PRB by removing the substrate.

[FIG. 13]

FIG. 13: Simplified diagram of port with coaxial connector.

[FIG. 14]

FIG. 14: Simplified diagram of port with via.

[FIG. 15]

FIG. 15: Simplified diagram of tuner top view.

[FIG. 16]

FIG. 16: Simplified diagram of triangular tuner top view.

[FIG. 17]

FIG. 17: Simplified diagram of tuner, motor and shaft cross section.

[FIG. 18]

FIG. 18: Simplified diagram of tuner with magnet, motor and shaft.

[FIG. 19]

FIG. 19: Simplified diagram of measurement system with DC block and amplifier.

[FIG. 20]

FIG. 20: Simplified diagram of measurement system with probe and attenuator.

[FIG. 21]

FIG. 21: Impedance matrix between LSI equivalent port and measurement port.

### DESCRIPTION OF EMBODIMENTS

In all the following figures the relative dimensions and the shapes do not represent the real proportions and shapes unless when it is explicitly mentioned in the text. The figures are only diagrammatic representations for the purpose of clarification. For example, the number of outer edges of one PCB does not need to be four even if in the figure only four edges are present.

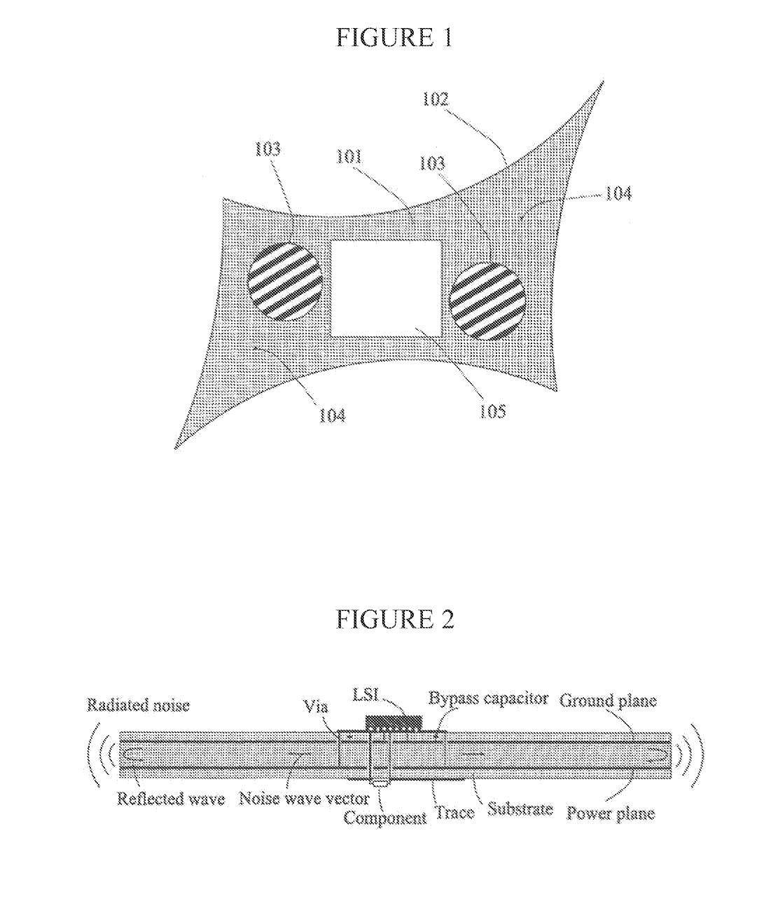

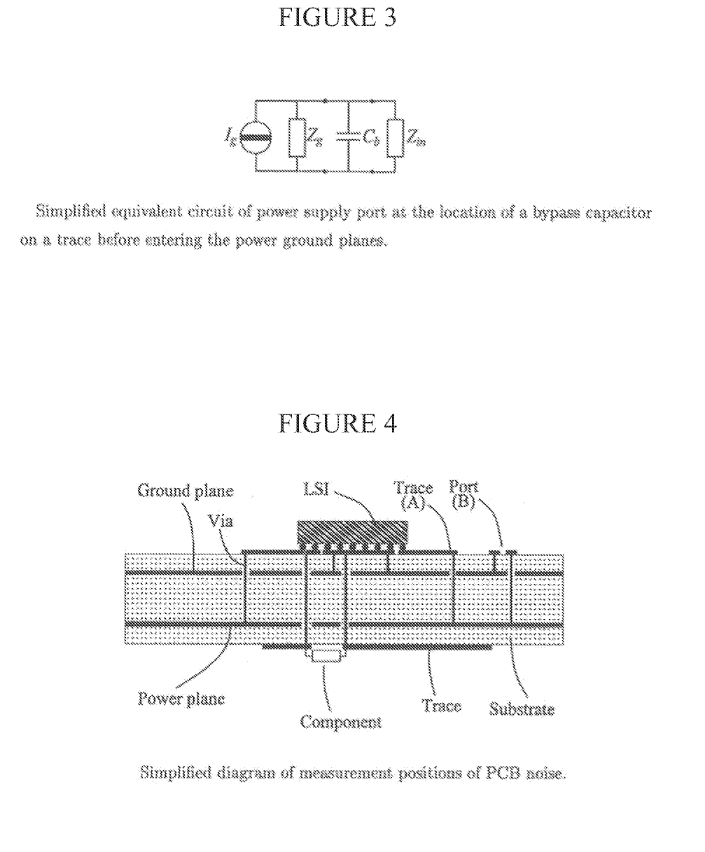

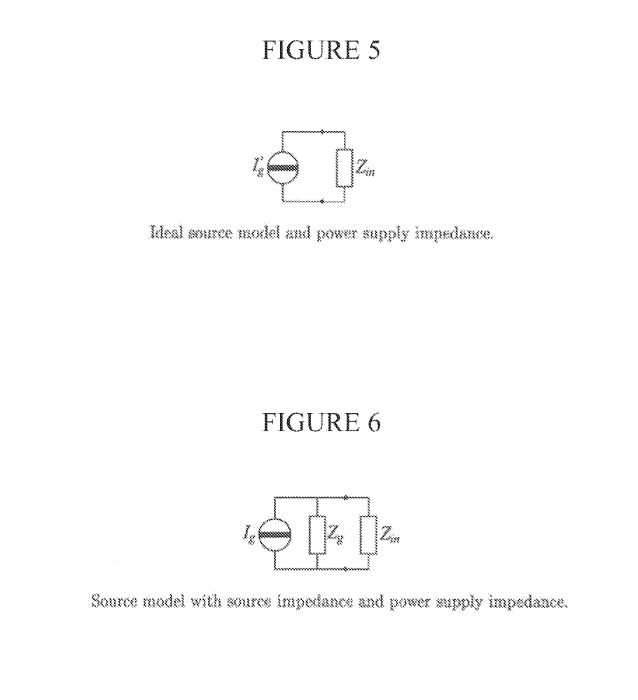

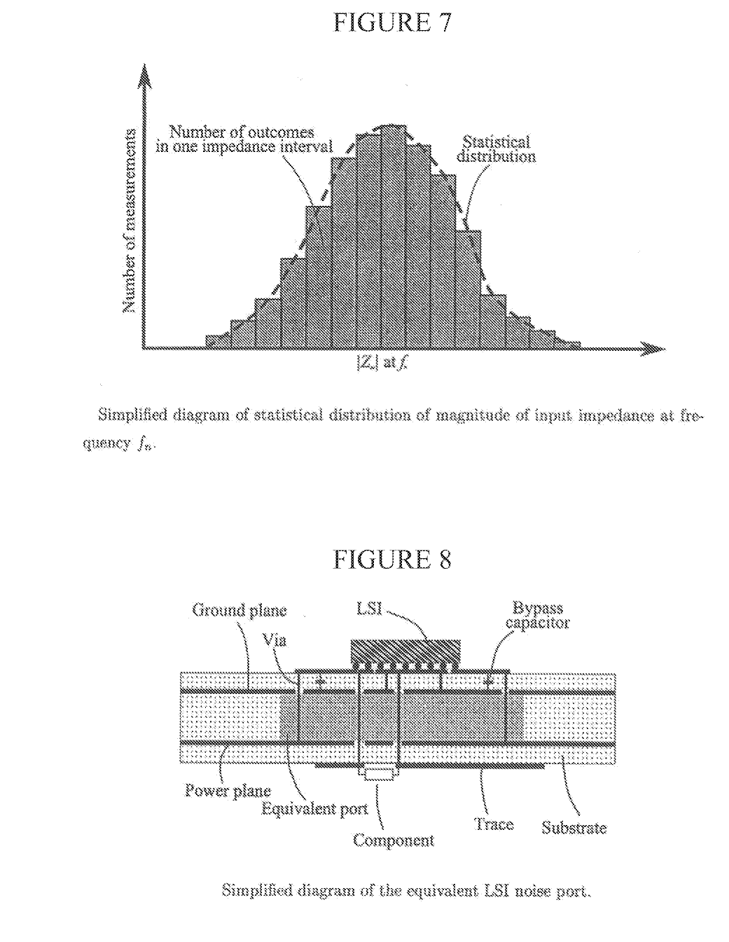

The preferred embodiment is the PRB 101 shown in FIG. 1, where the edges 102 are arcs of circles with different radii and with centers positioned on skew lines. The preferred embodiment also comprises one or a plurality of tuners 103, one or a plurality of ports 104, and one hole 105 for the equipment under test.

The shape in FIG. 1 is particularly simple to design and ensures wave chaotic conditions. Other shapes are well known to create wave chaotic conditions. For example some possible shapes are described in the non-patent document 3. Shapes having concave edges and not having special symmetries are suitable to generate wave chaotic conditions for sufficiently high frequencies and sufficiently low losses. Other embodiments comprise boards of shape different from that shown in FIG. 1, but suitable to create wave chaotic conditions. In yet other embodiments the wave chaotic conditions do not need to be created, but a statistical uniform environment is created, for example with a sufficiently low-loss and large board, and with a method to sufficiently modify the boundary conditions, such as large tuners or discrete components.

It must be also said that the wave chaotic conditions need to be only approximately verified, because some imperfections can be within the required measurement accuracy, and other imperfections can be adjusted with suitable calculations during the calibration phase of the board. Similarly, when the statistical uniformity is not strictly realized, a statistical model of the board can be obtained during the calibration phase.

In the preferred embodiment the planes are not connected at the edges 102 of the board, and the reflections at the edges are due to approximate open conditions, similarly to a typical PCB. In another embodiment the planes are connected at high frequencies all along the edges 102 by means of a plurality of capacitors at a distance from each other much smaller that the wavelength at the frequencies of interest. In this way the quality factor of the resonances is increased.

In yet another embodiment the printed circuit board has a rectangular shape or any other shape, and closely spaced capacitors draw a resonating two dimensional structure with curved edges on the power and ground planes, in order to generate wave chaotic conditions in only one portion of the PRB.

In order to conduct measurements in the preferred embodiment shown in FIG. 1, the EUT must be inserted into the hole 105.

A schematic representation of the invention with the EUT is shown in FIG. 10. The EUT 1001 is a printed circuit board containing the LSI acting as noise source, and the minimum components, traces and vias necessary to activate the LSI. Since this invention focuses on the power supply planes, the top and bottom layer of the EUT can be accessed for activating the LSI or the board, for example by means of cables, without strongly affecting the measurement results.

The noise is measured for one fixed position of the tuners 103. After each measurement at least one of the tuners is rotated of an angle different from 360 degrees, and the process is repeated for a number of times depending also on the required accuracy. Alternatively, the tuners (stirrers in this case) can be also kept rotating during measurements, similarly to the reverberation chamber.

In a different embodiment the PRB and the EUT are the same board, or in other words, the LSI is mounted directly on the PRB.

One advantage of the hole 105 in the preferred embodiment is that the PRB can be made with low-loss materials, while the EUT can be made with the original material, which usually contains considerable loss. Another advantage is that the board can be used for different EUTs.

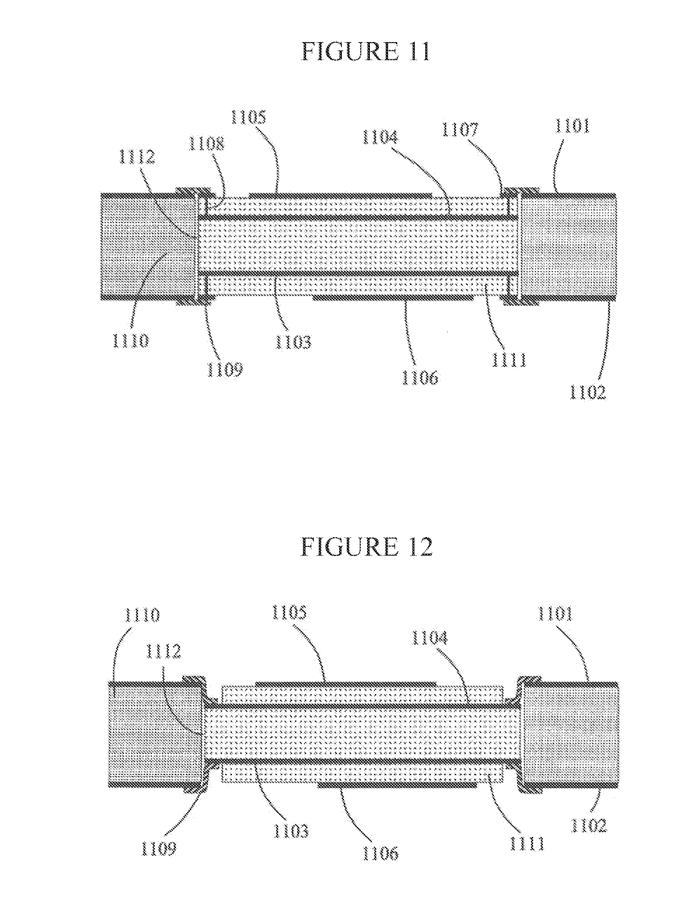

A schematic representation of the connection between the EUT and the PRB in the preferred embodiment is shown in FIG. 11. In order to convey the EUT power supply noise to the printed reverberation board, a continuation of the electrically conducting and dielectric media must be provided. The thickness of the EUT and the PRB does not need to be the same. In the preferred embodiment, the thickness of the PRB is the same as that of the EUT, and it is larger than that of the EUT power ground planes of interest. The number of layers of the EUT and of the PRB does not need to be the same.

The PRB must have at least two layers containing one plane. The number of the PRB layers in the preferred embodiment is two (1101 and 1102), because it is the smallest acceptable number. In other embodiments the number of metal layers can be larger than two, but two layers should contains planes having the same function of layers one 1101 and two 1102 in the preferred embodiment. The EUT in FIG. 11 has four layers, but it can have also a smaller or a larger number of layers.

For the conducting continuation, the power supply planes of interest of the EUT, 1103 and 1104, must be accessible from the first and last layers, 1105 and 1106, respectively, for example by means of pads 1107 and blind vias 1108 all along the perimeter of the EUT (FIG. 11), or by removing one portion of the substrate and pattern layers all along the perimeter (FIG. 12). A connection 1109 between the EUT power supply planes and the PRB first and second layer can be realized for example by means of a conducting tape, or by means of a clamp. Similar techniques can be used for the embodiment with a PRB of more than two layers, in order to access the two layers of interest.

For the dielectric continuation, the real part of the dielectric constant of the PRB substrate 1110 should be as close as possible to that of the EUT substrate 1111, reducing in this way the reflection at the interface between the two substrates. In principle the same material of the EUT could be used, but since the presence of the PRB resonances are important for the success of the measurements, a low loss material is preferable. The PRB conductor losses should be also made as small as possible. In practice a small gap 1112 is likely to appear at the interface between the PRB and the EUT substrates. This gap should be made as small as possible, or should be filled with a fluid dielectric low-loss material with dielectric constant similar to the PRB and the EUT.

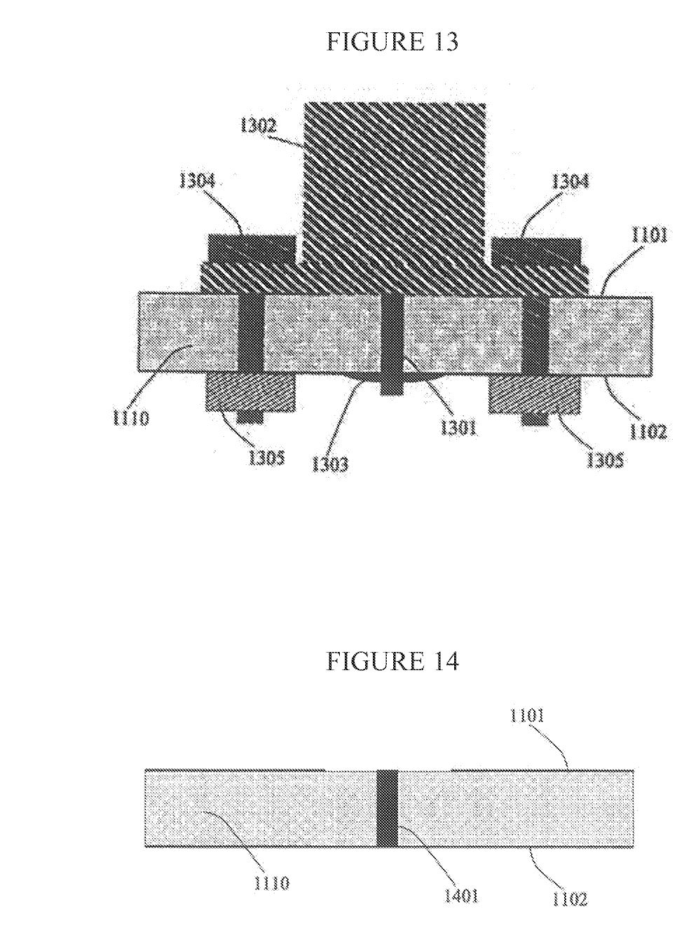

One or a plurality of ports 104 are present in the preferred embodiment. The ports do not need to be in the exact position as indicated in FIG. 1. A port must provide access to the PRB planes, such as the layer one 1101 and two 1102 in the preferred embodiment of FIG. 13. In this embodiment the center conductor 1301 of the coaxial connector 1302 is used by connecting it with solder 1303 to layer two. Non-conducting screws (e.g. the plastic screws 1304 which are fixed with the bolts 1305) are used, in order to connect the coaxial connector to layer one by avoiding short-circuiting the power supply planes. The dielectric constant of the screws should be close to that of the substrate 1110, in order to reduce the reflections. Alternatively or additionally to the screws, the connector can be soldered also to layer one.

In the embodiment of FIG. 14, access to layer two (1102) is provided by means of the through via 1401. In this figure, 1101 represents layer one of the PRB, and 1110 represents the PRB substrate. Other types of high frequency ports are possible, as long as access to both layers is provided.

In a different embodiment without ports, measurements are conducted at the LSI pins (or traces), for example by means of a near field current probe, the 1 Ohm method or similar methods. Measurements at the PRB port and at the LSI pins can be also combined in order to improve the LSI noise model.

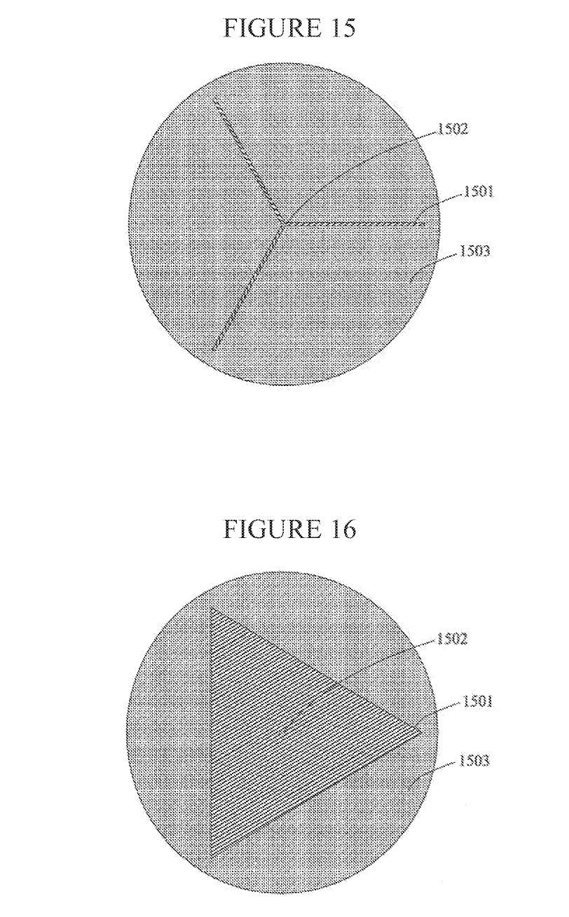

The tuners in the preferred embodiment are rotating PCBs containing conducting paddles 1501 and a hole 1502 in the center for the shaft. The number and shape of the paddles is not fixed. Two possible embodiments are shown in FIGS. 15 and 16, wherein the number of paddles must not be intended as three, but they can be also a larger or smaller number.

The top and bottom conducting patterns of the tuner must be electrically connected at all frequencies of interest. If the connection is made by means of through vias, the separation among the vias must be much smaller than the minimum wavelength of interest. Alternatively the paddles can be realized for example by means of blocks of conducting materials that are inserted into apertures provided in the PRB.

Since the continuity of the dielectric permittivity should be preserved, and a low loss material should be used, for the tuner substrate 1503 the same material as for the PRB can be used.

In the preferred embodiment the paddles are rotated by means of a stepping motor and a shaft made of a non conducting material (e.g. plastic). The shaft is inserted into the hole 1502 directly provided into the tuner's PCB.

In a different embodiment the shaft is attached to the tuner by means of a non-conducting (e.g. plastic) screw and a bolt that is inserted into the tuner's PCB. Other embodiments that provide a transmission of the torque from the shaft to the tuner are possible. In any case it is important to maintain the shaft diameter as small as possible, in order to reduce the dimensions of the hole that must be created into the tuner cover.

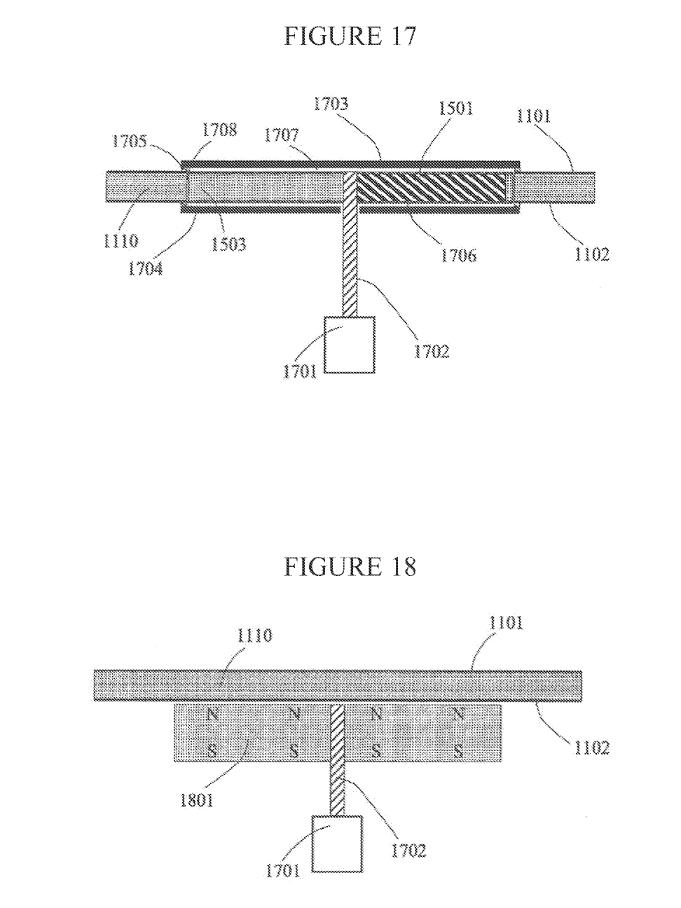

FIG. 17 represents schematically a cross sectional view of one tuner, together with the stepping motor 1701 and the motor shaft 1702. Each tuner must be covered with two conducting top (1703) and bottom (1704) covers, which do not rotate with the tuner. In order to provide a continuation for the current flowing on the power supply planes, the covers must be connected to layers one (1101) and two (1102) of the PRB by means of the connection support 1705, for example a conducting tape, a shielding gasket or soldering material. In order to avoid short circuiting the power ground planes of the EUT, it is preferable to cover the paddles 1501 with the thin layer of insulating material 1706 (e.g. solder resist).

Between the cover and the tuner, the gap 1707 can be required in some embodiments, in order to reduce the friction between tuner and cover, considering also some inaccuracies in the real arrangement. This gap should be kept as small as possible, because it reduces the reflection of the electromagnetic wave by the paddle, and therefore also the efficiency of the tuner. For the gap 1708 between the tuner substrate 1503 and the PRB substrate 1110, the same observations as for the gap between EUT and PRB are valid.

In the different embodiment of FIG. 18 the tuners are external to the board and comprise strong enough magnets (1801) or electromagnets generating a magnetic field oriented vertically towards the board. The magnet in the figure is only on one side of the PRB, but it can be also on both sides, in order to provide a stronger and more uniform magnetic field. The magnets needs to have a cross sectional shape different from the circular one, in order to generate a different magnetic field distribution when they are rotated by means of the stepping motor 1701 and the motor shaft 1702. For example a rectangular or a triangular cross section, or other convex or concave shapes are possible.

The principle of the mechanism is to use the analogue of the Lorentz force inside conductors to deflect the moving electrons in the high frequency power supply noise current inside the PRB. Different magnetic field configurations correspond to different deflection patterns, and therefore to different board resonances, as long as the field is strong enough to provide sufficient deflection. The main advantage of this embodiment is that a perfect continuation of the conducting layers one 1101 and two 1102, and of the dielectric substrate 1110 is provided at the tuner location.

In a different embodiment the tuners are not rotated, but different magnetic field distributions are created by means of an electrical circuit controlling the current into the electromagnets.

In another embodiment, variable capacitors between power and ground planes are added in some positions of the PRB, in order to change the boundary conditions, and therefore the power supply impedance. The capacitors are electrically controlled and can be used together with the tuners or instead of the tuners.

In a different embodiment the capacitors have fixed value and are used in order to modify the average board impedance, whereas the boundary conditions are changed with the tuners. The effect of these capacitances should be taken into account in the calibration of the board and in the preparation of the LSI noise model.

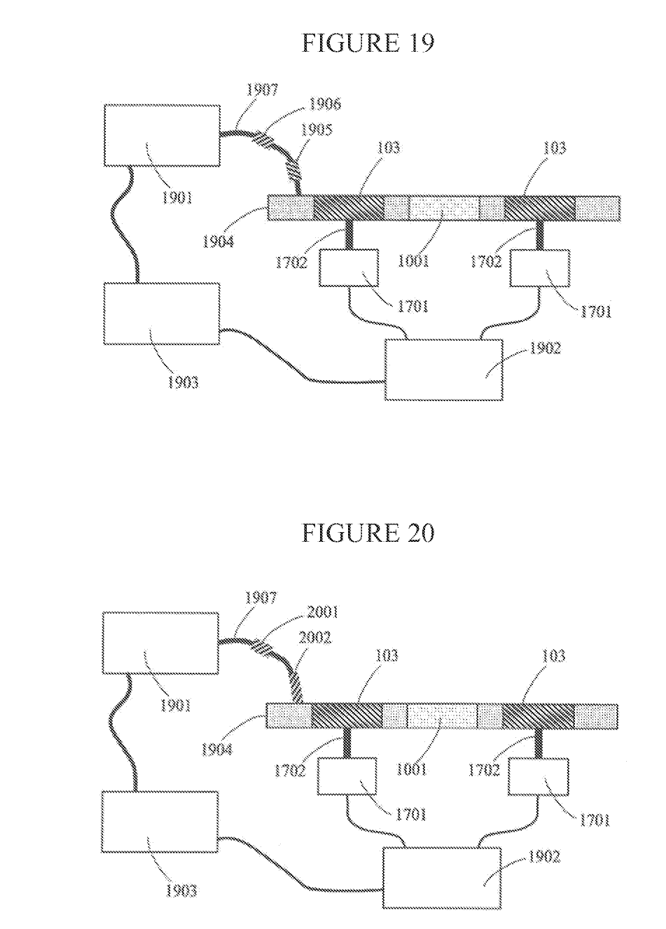

One embodiment of the present invention is the measuring systems of FIG. 19, which comprises one measurement equipment 1901, one or a plurality of motor drivers 1902 (also called motor controllers), one computer 1903 to control them, one or a plurality of motors 1701 and shafts 1702 to rotate the tuners 103, the PRB 1904, the EUT 1001, and one or a plurality of cable systems.

Since the layers one and two of the PRB, are connected to the power and ground planes of the EUT, in some equipments it is sometimes better or even necessary to remove the DC component of the signal, for example by means of a DC block component 1905. Depending on the measurement equipment, it is sometimes convenient to use an amplifier 1906 in series with the cable 1907, whereas in other situations it is better to insert the attenuator 2001 of FIG. 20, which shows a different embodiment comprising one passive or active probe 2002 at least at one PRB port. In this patent a cable system indicates the cables 1907 to connect the measurement equipment to the PRB port or to the probe, but it may also comprise one DC block component, one or a plurality of amplifiers, one or a plurality of attenuators, one or a plurality of filters, or any combination thereof.

The measurement equipment 1901 can be either a time domain or a frequency domain measurement equipment, for example a spectrum analyzer or a digital oscilloscope, or any single or multiport equipment with similar functions. The equipment can have a high impedance input port, or a 50 Ohm port, or an input port with a different impedance. The high impedance port has the advantage that it does not load the PRB port.

In a different embodiment, the measurement equipment 1901 is replaced by a noise generator, and the present invention is used to test the immunity of one or a plurality of LSIs to power supply noise. In this case the ports are used to inject some signal acting as noise, and the effect on the functionality of the LSIs can be observed or measured.

One possible method for extracting the LSI model is disclosed in the following. The purpose of this disclosure is to provide one possible way to use the present invention to extract an LSI noise model.

The method is based on the theory developed in the non-patent reference 2, and in particular on Formula 1, which expresses the impedance matrix

$$\overline{\overline{Z}}$$

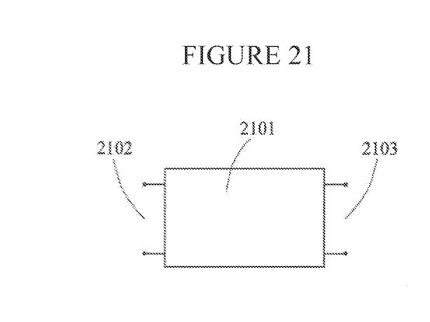

of the two-port network 2101 between the LSI equivalent port 2102, and the measurement port 2103 on the PRB, as shown in FIG. 21, in terms of the impedance matrix

$${\overline{\overline{Z}}}_{rad}$$

(with elements Z_{11rad}, Z_{12rad}, Z_{21rad}, Z_{22rad}) between ports at the same distance in a hypothetical infinite board, and of the so-called ‘universal impedance matrix’

$$\overline{\overline{z}} ,$$

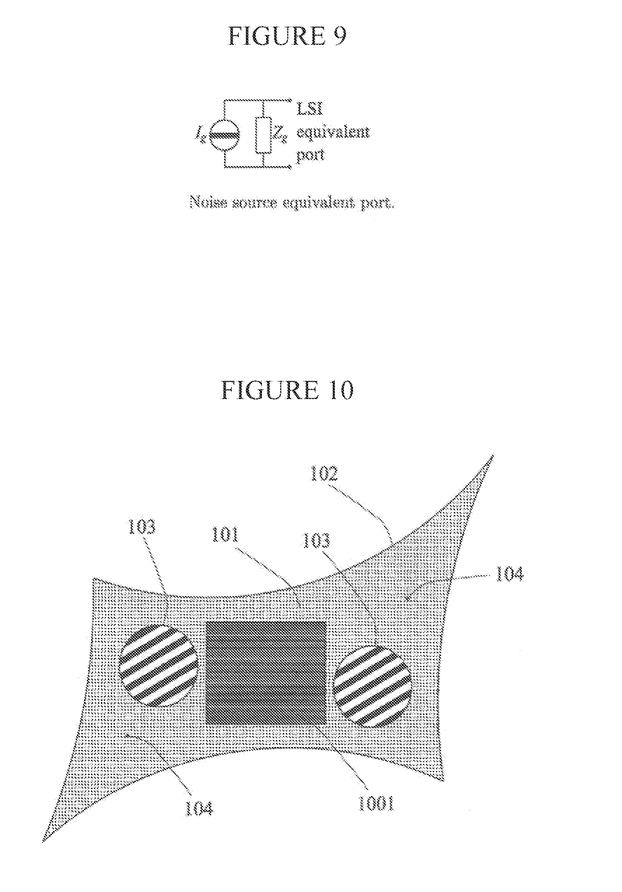

which is a random matrix that characterizes the particular board. The LSI equivalent port 2102 was introduced in the summary of the invention with FIG. 9. When the statistical uniform condition is verified in the non-strict sense. Formula 1 is valid only for the strictly statistically uniform part only.

$$\overline{\overline{Z}} = j Im [ {\overline{\overline{Z}}}_{rad} ] + {( Re [ {\overline{\overline{Z}}}_{rad} ] )}^{1 / 2} {\overline{\overline{z}} ( Re [ {\overline{\overline{Z}}}_{rad} ] )}^{1 / 2} \qquad ( Formula 1 )$$

The method is divided into the following two sequences of steps, the sequences 1 and 2,

1. This is a preliminary work to characterize one particular PRB design, and it does not need to be repeated for each measurement on a particular EUT. It can be thought as a sort of calibration of the PRB. It can be done based on measurement results, on simulation results, on theoretical results or on a combination of them. The fundamental steps can be described as follows:

A) characterization of the passive board (no EUT, no hole) based on universal cavity impedance matrix z̅;

B) determination of measurement port impedance and transfer impedance between LSI position and measurement port position for a hypothetical infinite board (Z_{22rad}, Z_{21rad});

C) in the non-strictly statistically uniform case, the determination of the impedance matrix for the finite PRB with and/or without the stirrer might be also required.

2. This sequence must be done for each particular EUT in order to extract the LSI model. The fundamental steps can be described as follows:

A) select a starting value for source (I_{g}), source impedance (Z_{g}), and for the port impedance of an hypothetical infinite board (Z_{11rad});

B) calculate the expected probability density function of the voltage at the measurement port using Formula 1 and eventually, in the non-strictly statistically uniform case, also using the impedance matrix for the finite PRB;

C) compare probability density function with distribution of measurement data. If the accuracy is not sufficient, modify the source, source impedance and port impedance values and repeat steps (B) and (C) until sufficient accuracy is obtained.

### REFERENCES SIGNS LIST

101 PRB (printed reverberation board)
102 Edge
103 Tuner
104 Port
105 Hole for equipment under test
1001 EUT (equipment under test)
1101 PRB layer 1
1102 PRB layer 2
1103 EUT layer 2
1104 EUT layer 3
1105 EUT layer 1
1106 EUT layer 4
1107 Edge pad
1108 Blind via
1109 Connection
1110 PRB substrate
1111 EUT substrate
1112 Gap
1301 Center conductor
1302 Coaxial connector
1303 Solder
1304 Plastic screw
1305 Bolt
1401 Via
1501 Paddle
1502 Shaft hole
1503 Tuner substrate
1701 Stepping motor
1702 Shaft
1703 Top cover
1704 Bottom cover
1705 Connection support
1706 Insulating layer
1707 Gap 1
1708 Gap 2
1801 Magnet
1901 Measurement equipment
1902 Motor driver
1903 Computer
1904 PRB
1905 DC bLock
1906 Amplifier
1907 Cable
2001 Attenuator
2002 Probe
2101 Two-port network
2102 LSI equivalent port
2103 LSI measurement port

1. An apparatus for measuring electromagnetic noise in an EUT (Equipment under test) comprising:
a PRB (printed reverberation board),
a hole on the PRB for inserting the EUT,
two conductive layers formed on both sides of the PRB
and a high frequency measurement port on the PRB for measuring an electromagnetic wave in the PRB.

2. The apparatus for measuring electromagnetic noise in an EUT according to claim 1,
further comprising,
a tuner for changing boundary conditions of electromagnetic field.

3. The apparatus for measuring electromagnetic noise in an EUT according to claim 1,
wherein the PRB has a plurality of curved edges.

4. The apparatus for measuring electromagnetic noise in an EUT according to claim 1,
wherein the EUT is a PCB (printed circuit board),
and the PCB is inserted in direction coplanar to the PRB.

5. The apparatus for measuring electromagnetic noise in an EUT according to claim 1,
wherein instead of the hole for the EUT, the PRB contains the EUT in the same printed circuit board.

6. The apparatus for measuring electromagnetic noise in an EUT according to claim 1,
wherein the two conductive layers are electrically connected to the EUT.

7. The apparatus for measuring electromagnetic noise in an EUT according to claim 2,
wherein the tuner has one or a plurality of rotating elements formed of conductive material.

8. The apparatus for measuring electromagnetic noise in an EUT according to claim 2,
wherein the tuner has a magnet for generating in the PRB a magnetic field.

9. The apparatus for measuring electromagnetic noise in an EUT according to claim 2,
wherein electromagnetic field boundary conditions are changed by means of capacitors betweenthe PRB conducting layers.

10. A method for measuring electromagnetic noise in an EUT (Equipment under test) comprising:
a step of inserting the EUT into a hole on the PRB,
a step of activating the EUT,
a step of guiding the electromagnetic wave generated by the EUT into the PRB, and a step of measuring the electromagnetic wave with a high frequency measurement port on the PRB.

11. The method for measuring electromagnetic noise in an EUT according to claim 10,
further comprising,
a step of changing a boundary condition of the electromagnetic wave in the PRB by means of the tuner.

12. The apparatus for measuring electromagnetic noise in an EUT according to claim 11,
wherein wave chaotic conditions are realized by the change of boundary conditions

13. The apparatus for measuring electromagnetic noise in an EUT according to claim 10,
wherein the PRB has a plurality of curved edges.

14. The apparatus for measuring electromagnetic noise in an EUT according to claim 10,
wherein in the step of activating the EUT, an electrical power be supplied via conductive layers formed on the PRB.

15. The apparatus for measuring electromagnetic noise in EUT according to claim 10,
wherein the EUT is a PCB (printed circuit board),
and in the step of inserting the EUT, the PCB is inserted in direction coplanar to the PRB.

16. The apparatus for measuring electromagnetic noise in an EUT according to claim 11,
wherein the tuner has in the PRB a rotating element formed of conductive material.

17. The apparatus for measuring electromagnetic noise in an EUT according to claim 11,
wherein the tuner has a magnet for generating a magnetic field in the PRB.

18. A method for testing an EUT immunity to electromagnetic field comprising:
a step of inserting the EUT into a hole on the PRB,
a step of activating the EUT,
a step of injecting electromagnetic field into the PRB through a high frequency port or froma source mounted on the PRB,
a step of guiding the electromagnetic wave from the PRB into the EUT,
and a step of verifying the functionality of the EUT.

19. The method for testing an EUT immunity to electromagnetic field according to claim 18, further comprising,
a step of changing a boundary condition of the electromagnetic wave in the PRB by means of the tuner.

20. The apparatus for testing an EUT immunity to electromagnetic field according to claim 18,
wherein the PRB has a plurality of curved edges.
